(19) United States
(12) Patent Application Publication
(10) Pub. No.: US 2009/0096351 A1
(43) Pub. Date: Apr. 16, 2009

(54) REFLECTIVE LAYERS FOR ELECTRONIC DEVICES

(75) Inventors: Mark J. Hampden-smith, Albuquerque, NM (US); Mark H. Kowalski, Albuquerque, NM (US)

Correspondence Address: Patent Administrator;Cabot Corporation, 5401 Venice Avenue, NE, Albuquerque, NM, 87113, US

(73) Assignee: Cabot Corporation, Boston, MA (US)

(21) Appl. No.: 11/871,363

(22) Filed: Oct. 12, 2007

(51) Int. Cl. H01J 1/63; H01L 33/00; B05D 5/12; H01L 31/18; H01L 31/0232

(52) U.S. Cl. 313/504; 257/98; 427/66; 136/256; 438/72; 257/E33.067; 257/E31.127

(57) ABSTRACT

Reflective electronic layers are provided for electronic devices, such as electroluminescent lamps, photovoltaic devices, and light emitting diodes. Processes for forming such reflective layers are also provided. The reflective layers comprise metallic particles that optionally are coated.

### BACKGROUND OF THE INVENTION

1. Field of the Invention

The present invention relates to electronic layers. More particularly, the invention relates to reflective electronic layers such as reflective conductive layers (e.g., reflective electrode layers), reflective resistor layers and reflective dielectric layers, and to devices comprising these layers such as electroluminescent lamps, photovoltaic devices and light-emitting diodes.

2. Discussion of the Background Information

Many electronic devices comprise electronic layers that have the function of providing conductivity, a particular resistivity or an insulating or dielectric function. A number of these electronic devices also have the function of interacting with or emitting electromagnetic radiation that can be in the region of visible light, UV light or infra-red light. Examples of such devices include, for instance, electroluminescent (EL) lamps, photovoltaic devices and light emitting diodes. In general, the electronic layers (conductive, resistive, insulative or dielectric layers) in these devices are formed from flakes or particles having an average size greater than 1 mm, which undesirably leads to scattering of the light (whether incident light, such as in the case of a photovoltaic cell, or emitted light such as in the case of EL lamps and light emitting devices) and decreased efficiency. Thus, the need exists for improving the efficiency of devices having electronic layers, particularly those devices that interact with or emit electromagnetic radiation that can be in the region of visible light, UV light or infra-red light.

Electroluminescent (EL) lighting has been known for many years as a source of light weight and relatively low power illumination. Because of these attributes, EL lamps are in common use today providing light in, for example, automobiles, airplanes, watches, cell phones, and laptop computers. EL lamps generally include a layer of phosphor particles positioned between a front light-transmissive (e.g., translucent) electrode and a back electrode. EL lamps also typically include a dielectric layer, which enables the lamp's capacitive properties, positioned between the back electrode and the layer of phosphor particles. When a voltage is applied across the electrodes, e.g., via electrode leads or bus bars that are in electrical communication with the electrodes, the phosphor material is excited and radiates light through the front electrode.

Conventional light-transmissive front electrodes are formed of a polyester film sputtered with a transparent conductor such as indium-tin-oxide, which provides a serviceable translucent material with suitable conductive properties for use as an electrode. Screen-printed ink systems have also been employed for depositing a transparent conductor, typically in a resin, onto a substrate to form the front electrode. Another known method of fabricating an EL lamp includes the steps of applying a coating of light-transmissive conductive material, such as indium tin oxide, to a rear surface of polyester film, etching the film to create a pattern, applying a phosphor layer (e.g., comprised of barium-titanate particles suspended in a cellulose-based resin) to the conductive material, applying at least one dielectric layer to the phosphor layer, applying a rear electrode to the dielectric layer, and applying an insulating layer to the rear electrode. EL lamps in the art typically are manufactured as discrete cells on either rigid or flexible substrates. In order to obtain a colored graphical display, the graphical layers are separately constructed and then the various layers may, for example, be laminated together utilizing heat and pressure. Alternatively, the various layers may be screen printed to each other.

Conventionally, the back (or rear) electrode is opaque or has a low reflectivity value. For example, many conventional EL lamps use carbon or silver flake (i.e., silver deposited in a diffuse, non-reflective configuration) for the back electrode. Referring to FIGS. 1 and 2, the reflectivity of the back electrode depends upon the wavelength of the light and the angle of incidence. However, for carbon and silver flake back electrodes, even at an angle of 60 degrees, the reflectivity is less than 12%, and at lesser angles, the reflectivity is significantly less than 10%. Accordingly, much of the light that is radiated from the phosphor layer is absorbed by the back electrode rather than being emitted through the front electrode, resulting in reduced EL lamp efficiency. Thus, the need exists for improving EL lamp efficiency.

This need is not limited to EL lamps, and generally exists for any light-emitting device which is intended to emit light from a front face. Another example is a light-emitting diode. In the case of a white LED, a phosphor is excited by blue light and emits in all directions. Much of the radiation that is emitted, however, is typically absorbed by the back electrode leading to reduced device efficiency. Thus, the need also exists for improving the efficiency of light-emitting devices, e.g., LED's.

In the case of a photovoltaic device, light is converted into electricity by a semiconductive layer. The electricity produced is removed from the semiconductor device though electrodes attached to the substrate. In many cases the light can penetrate the entire thickness of the semiconductor device and is absorbed by the back electrode of the device. As a result, a portion of the incident radiation is not converted into electricity, resulting in reduced photovoltaic efficiency. Thus, the need also exists for improving the efficiency of photovoltaic devices, e.g., solar cells.

### SUMMARY OF THE INVENTION

In various embodiments, the present invention is directed to: (a) reflective electronic layers such as reflective conductive layers (e.g., reflective electrode layers), reflective resistor layers and reflective dielectric (e.g., insulator) layers; (b) to devices that comprise such reflective electronic layers such as electroluminescent lamps, photovoltaic devices and light-emitting diodes; (c) to processes for forming such reflective electronic layers; and (d) to processes for forming such devices.

The reflective electronic layers preferably comprise metallic particles having an average size that is less than 500 nm, e.g., less than 400 nm, less than 300 nm, less than 200 nm or less than 100 nm. The metal particles optionally are coated with a layer such that when they are printed they exhibit: (i) metallic conductivity (a reflective electrode), (ii) resistance controllable over a large range (iii) insulation (no conductivity whatsoever). This may be achieved by coating the particles with (i) (for high conductivity) a polymer (which enables conductivity), (ii) (for a resistor) a low temperature melting glass (which melts to various extents as a function of temperature to which the layer is heated to give various different levels of resistance) or a conductive glass/metal oxide or other layer that imparts some reduced level of conductivity, or (iii) (for a reflective insulating layer) a glass/metal oxide (or any other insulating coating) that results in electronically insulating the metal particles such that they remain reflective, but have no conducting path.

In one aspect, the invention is to an electronic device comprising a printed reflective electronic layer comprising metallic particles having an average particle size less than 300 nm, e.g., less than 200 nm, or less than 100 nm, wherein the printed reflective electronic layer has a reflectivity greater than 20%, e.g., greater than 40%, greater than 60% or greater than 80%.

In another embodiment, the invention is to an electronic device having resistive printed reflective electronic layer. For example, in this aspect, the electronic device optionally comprises a printed reflective electronic layer comprising metallic particles having an average particle size less than 300 nm, e.g., less than 200 nm or less than 100 nm, wherein the printed reflective electronic layer has an average reflectivity greater than 20%, e.g., greater than 40%, greater than 60% or greater than 80%. over a wavelength from 300 to 750 nm (optionally over a wavelength from 250 to 25,000 nm), and the printed reflective electronic layer has a resistivity greater than 1 Ω/square, e.g., greater than 100 Ω/square, greater than 1,000 Ω/square, or greater than 1,000,000 Ω/square. Optionally, the reflective electronic layer has an average reflectivity greater than 80% over a wavelength of 300 to 750 nm. In one preferred embodiment, the device is an electroluminescent lamp and the reflective electronic layer is a reflective dielectric layer in the electroluminescent lamp. In another embodiment, the electronic device is a light emitting diode, and the reflective electronic layer acts as a reflective electrode

In another embodiment, the invention is to an electroluminescent lamp, comprising a first electrode layer comprising metallic particles, the first electrode layer having an average reflectivity greater than 20%, e.g., greater than 40%, greater than 60% or greater than 80%, over a wavelength from 300 to 750 nm (optionally over a wavelength from 250 to 25,000 nm). The lamp optionally further comprises either (i) a dielectric layer and a phosphor layer, or (ii) a composite layer comprising a dielectric material and a phosphor material; and a second electrode, preferably disposed opposite the first electrode layer with dielectric and phosphor layers or the composite layer disposed between the two electrode layers. The metallic particles preferably have an average particle size of less than 300 nm, e.g., less than 200 nm or less than 100 nm.

In another embodiment, the invention is to a process for forming an electrode for an electroluminescent lamp, comprising depositing an ink comprising metallic particles and a vehicle onto a substrate and removing the vehicle to form a first electrode layer, wherein the first electrode layer has an average reflectivity greater than 20%, e.g., greater than 40%, greater than 60% or greater than 80%, over a wavelength from 300 to 750 nm (optionally over a wavelength from 250 to 25,000 nm). The metallic particles preferably have an average particle size of less than 300 nm, e.g., less than 200 nm or less than 100 nm. The substrate preferably comprises either (i) a dielectric layer and a phosphor layer, or (ii) a composite layer comprising a dielectric material and a phosphor material; and optionally a second electrode layer. The step of depositing optionally comprises printing with a printing process selected from the group consisting of gravure, offset, screen, flexography, direct write, syringe, and ink jet printing.

In another embodiment, the invention is to a photovoltaic device comprising: (a) a semiconductor substrate; (b) a front grid electrode disposed on a first side of the semiconductor substrate; and (c) a back electrode disposed on a second side of the semiconductor substrate, the back electrode comprising a printed reflective electronic layer comprising metallic particles, wherein the printed reflective electronic layer has an average reflectivity greater than 20%, e.g., greater than 40%, greater than 60% or greater than 80%, over a wavelength from 300 to 750 nm (optionally over a wavelength from 250 to 25,000 nm). The metallic particles preferably have an average particle size of less than 300 nm, e.g., less than 200 nm or less than 100 nm. The semiconductor substrate optionally comprises an n-type silicon layer and/or a p-type silicon layer.

In another embodiment, the invention is directed to a process for forming a photovoltaic device, comprising: (a) forming a front grid electrode on a first side of a semiconductor substrate; (b) depositing an ink comprising metallic particles and a vehicle onto a second side of the semiconductor substrate; and (c) removing the vehicle to form a reflective electronic layer, wherein the reflective electronic layer is a back electrode of the photovoltaic device, and wherein the reflective electronic layer has an average reflectivity greater of than 20%, e.g., greater than 40%, greater than 60% or greater than 80%, over a wavelength from 300 to 750 nm (optionally over a wavelength from 250 to 25,000 nm). The step of depositing optionally comprises printing with a printing process selected from the group consisting of gravure, offset, screen, flexography, direct write, syringe, and ink jet printing. The metallic particles preferably have an average particle size of less than 300 nm, e.g., less than 200 nm or less than 100 nm. The semiconductor substrate optionally comprises an n-type silicon layer and/or a p-type silicon layer.

### BRIEF DESCRIPTION OF THE DRAWINGS

The present invention will be better understood in view of the following non-limiting figures, wherein:

FIG. 1 provides a graphical illustration of reflectivity versus wavelength for a conventional printed electrode comprising micron-sized metal conductor (silver flake) particles;

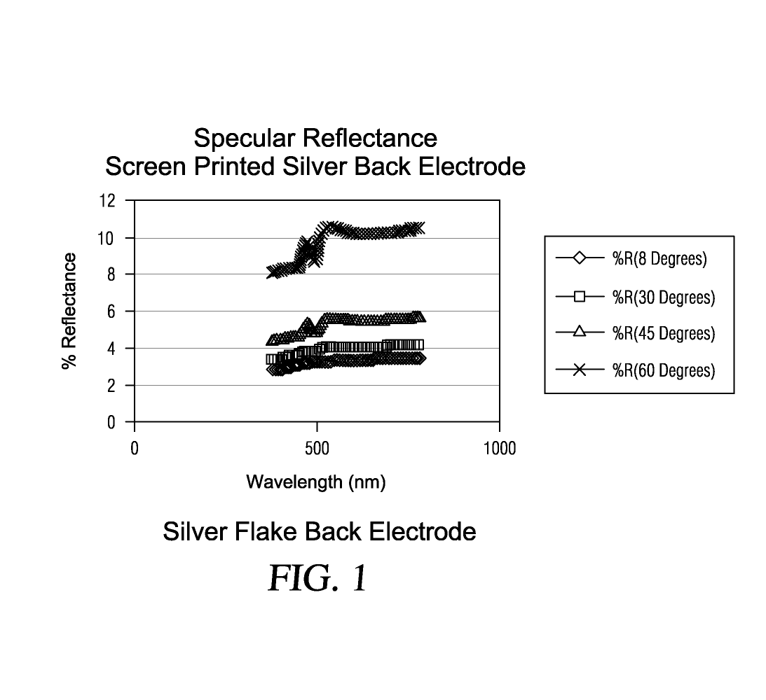

FIG. 2 provides a graphical illustration of reflectivity versus wavelength for a conventional printed electrode comprising carbon particles;

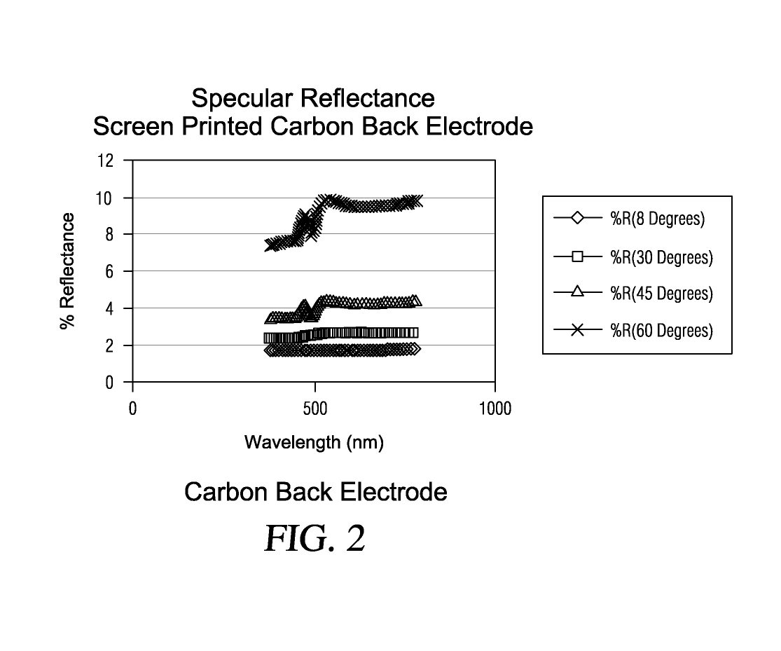

FIG. 3 provides an illustration of the components of an electroluminescent lamp having a reflective back electrode according to a first preferred embodiment of the present invention;

FIG. 4 provides an illustration of the components of an electroluminescent lamp having a reflective back electrode according to a second preferred embodiment of the present invention;

FIG. 5 provides a graphical illustration of reflectivity versus angle for a reflective layer according to a preferred embodiment of the present invention using two different types of metallic particles to form a conductive reflective electronic layer compared to a standard, non-reflective micron-sized particle pigment;

FIG. 6 provides a graphical illustration of reflectivity versus wavelength for a reflective layer according to a preferred embodiment of the present invention using two different types of metallic particles to form a conductive reflective electronic layer compared to a standard, non-reflective micron-sized particle pigment;

FIG. 7 provides a flow chart that illustrates a process for forming an electroluminescent lamp having a reflective back electrode according to a preferred embodiment of the present invention; and

FIG. 8 provides a flow chart that illustrates a process for forming a photovoltaic feature having a reflective back electrode according to a preferred embodiment of the present invention.

### DETAILED DESCRIPTION OF THE INVENTION

### Introduction

In various embodiments, the present invention involves employing fine metal particles (particles having an average particle size less than 500 nm, e.g., less than 400 nm, less than 300 nm, less than 200 nm or less than 100 nm) that exhibit high reflectivity of light from the UV through the infra-red range (including visible light) when printed. The particles optionally are coated with a material that facilitates the formation of reflective electronic layers such as reflective conductive layers, reflective resistive layers or reflective dielectric layers when printed. Several examples of devices that would benefit from highly reflective electronic layers are described below. In these cases, significant improvement in performance may be realized as a result of using an electronic layer that has the combined function of the desired electrical property (conductivity, insulation or resistance) and high reflectivity.

In another aspect, the reflective electronic layer includes first and second regions, wherein the first region has a greater thickness than the second region. Providing reflective electronic layers having regions of increased thickness may be particularly desirable in that they provide the ability to bend the device, e.g., EL lamp, LED, flexible photovoltaic feature, or other device, around corners in the region of greater thickness without unduly sacrificing conductivity around the corner. Thus, in another aspect, the device may be moldable and may be bendable around a corner. The first region may be aligned with the corner to provide conductivity and reflectivity around the corner.

### Reflective Electronic Layers

In various embodiments, the present invention is directed to reflective electronic layers, which may have conductive, resistive or dielectric properties, to devices employing reflective electronic layers, to processes for forming reflective electronic layers and to processes for forming devices employing reflective electronic layers.

As used herein, the term “reflective” means having an average reflectivity of greater than 12% over a wavelength from 300 to 750 nm (optionally from 250 to 25,000 nm or over wavelengths in the UV, visible and IR spectra). Thus, for purposes of the present specification, a reflective electronic layer is an electronic layer having a reflectivity of greater than 12%. The reflective electronic layer may have a reflectivity significantly greater than 12%. For example, in various embodiments, the reflective electronic layer optionally has a reflectivity greater than 20%, e.g., greater than 35%, greater than 50%, greater than 60%, greater than 75% or greater than 85%. Conversely, the term “non-reflective,” as used herein, means having a reflectivity less than 12% over a wavelength from 300 to 750 nm. For purposes of the present specification, unless otherwise specified, the reflectivity is determined at an angle of 60 degrees by a spectrometer (e.g., UV, visible, and/or IR spectrometer) capable of measuring specular and/or diffuse reflectance, e.g., a Perkin-Elmer Lambda 650 UV/V is spectrometer with universal reflectance and universal diffuse accessories.

In various optional embodiments, the reflective electronic layer may have a reflectivity at a wavelength of 750 nm of greater than 20%, e.g., greater than 35%, greater than 50%, greater than 60%, greater than 75%, greater than 85%, or greater than 90%. Additionally or alternatively, the reflective electronic layer may have a reflectivity at a wavelength of 300 nm of greater than 20%, e.g., greater than 35%, greater than 50%, greater than 60%, greater than 75%, greater than 85%, or greater than 90%. The reflective electronic layer preferably exhibits substantially specular reflectance. As used herein, the term “specular” means having mirror-like reflectivity. By contrast, as used herein, the term “diffuse” is defined herein as being non-reflective, i.e., having a reflectivity less than 12%. As used herein, the term “electronic layers” means layers that are utilized in a device or intended to be utilized in a device primarily for their electrical properties. A non-limiting list of types of electronic layers includes conductive layers, resistive layers, and dielectric layers.

The reflective electronic layers preferably comprise metallic particles. Employing fine metallic particles to form the reflective electronic layers increases the reflectivity that may be achieved relative to using larger metallic particles and flakes. Additionally, by employing fine metallic particles, reflective electronic layers may be formed at relatively low temperatures. The metallic particles may comprise non-aggregated primary metallic particles and/or aggregates of primary metallic particles.

Preferably, the reflective electronic layers comprise metallic particles (e.g., primary particles or aggregates of primary particles) having an average particle size, e.g., diameter for spherical particles, of less than 500 nm, such as less than about 400 nm, less than about 300 nm, less than about 200 nm or less than about 100 nm. For purpose of the present invention, the average particle size of the metallic particles is determined by transmission electron microscopy (TEM). If a high degree of conductivity is desired, the metallic particles in the reflective electronic layers preferably are sintered to adjacent metallic particles in an amount sufficient to create a percolation network for the desired degree of conductivity. In some embodiments, adjacent particles are sintered to one another and the metallic particles are still identifiable in the reflective electronic layer. In other embodiments, the metallic particles become “fully” sintered such that the metallic particles used to form the reflective electronic layer are no longer identifiable and a continuous metallic layer is formed. In still other embodiments, particularly those embodiments where conductivity is not desired, the metallic particles in the reflective electronic layers remain substantially unsintered.

As one skilled in the art will appreciate, the degree to which the nano-structure of the metallic particles remains in the reflective electronic layer will depend, primarily, on the temperature and duration at which the particles are heated during electrode formation.

The metallic particles may comprise any metal so long as the metal provides the desired level of conductivity and reflectivity for the resulting electrode. In some preferred embodiments, the metal may be silver, gold, copper, palladium, platinum, rhodium, and alloys thereof.

Preferably, the metallic particles are tailored for the particular type of reflective electronic layer formed. For example, for conductive applications, the metallic particles optionally include a polymer coating which facilitates dispersing the particles in ink formulations, and which will not significantly interfere with the any processing steps that are employed to sinter the metallic particles to one another.

In another embodiment, the metallic particles comprise a glass coating. Depending on the type and amount of glass coating employed, the metallic particles may be suitable for forming reflective conductive layers or reflective resistive layers. Importantly, the ratio of the amount of metallic composition to the glass employed may be specifically selected so as to provide an reflective resistive layer having the specifically desired resistivity. Generally, the greater the amount of glass composition relative to the amount of metallic composition employed, the greater the resistance of the reflective electronic layer that is formed. By carefully controlling the ratio of insulator, e.g., glass, to conductive phase, e.g., metallic composition, reflective electronic layers may be formed having a wide variety of resistivities. See U.S. patent application Ser. No. 11/765,313, filed Jun. 19, 2007, the entirety of which is incorporated herein by reference, for a disclosure of processes for forming glass coated metallic particles suitable for use in this aspect of the present invention.

In a similar embodiment, the metallic particles employed may comprise a coating comprising a glass or metal oxide. Depending on the amount and specific composition employed, glass/metal oxide coatings may be used to form reflective electronic layers having dielectric properties. Generally, the greater the amount of glass/metal oxide relative to the amount of metallic composition employed, the more dielectric the reflective electronic layer will be. The glass/metal oxide coating provides insulation between adjacent metallic particles and inhibits the formation of a percolation network therebetween. By carefully controlling the ratio of insulator, e.g., glass/metal oxide, to conductive phase, e.g., metallic composition, reflective dielectric layers may be formed having a wide variety of dielectric properties. If it is desired for the reflective electronic layer to have dielectric properties, for example, to form a reflective dielectric layer in an EL lamp, the reflective electronic layer optionally has a dielectric constant that is substantially equivalent to the dielectric constants for barium titanate, strontium titanate or lead titanate or other materials conventionally employed for forming dielectric layers, e.g., dielectric layers in EL lamps. Some difference in dielectric constant between the reflective dielectric layers of this aspect of the invention and conventional dielectric layers may exist so long as the reflective dielectric layer functions as desired.

The reflective electronic layer, whether employed in an EL lamp, photovoltaic feature, LED, or other device, may be particularly thin, e.g., having a thickness less than 50 μm, e.g., less than 10 μm, less than 5 μm, less than 1 μm, or less than 0.5 μm. In various optional embodiments, the average thickness of the resistor is greater than 0.01 μm, e.g., greater than 0.05 μm, greater than 0.1 μm, greater than 0.5 μm, greater than 1 μm, greater than 5 μm, greater than 10 μm, greater than 100 μm or greater than 1 mm. These thicknesses can be obtained by direct write, e.g., inkjet, deposition or deposition of discrete units of material in a single pass or in two or more passes. For example, a single layer can be deposited and dried, followed by one or more repetitions of this cycle, if desired. In various embodiments, the ink may be deposited in a printing process selected from the group consisting of gravure, offset, screen, flexography, direct write, syringe, and ink jet printing.

As indicated above, in various optional embodiments the reflective electronic layer has resistive properties. The optional resistivity of the reflective electronic layer of the present invention may vary widely depending, for example, on the types of conductive and resistive phases used to form the reflective electronic layer, the respective amounts of the conductive and resistive phases used to form the reflective electronic layer and the morphology of the conductive and resistive phases used to form the reflective electronic layer. Generally, the greater the volume ratio of conductive phase to resistive phase in the resistor, the more conductive (less resistive) the resistor will be. Conversely, the less the volume ratio of the conductive phase to the resistive phase in the resistor, the less conductive (more resistive) the resistor will be. In various embodiments, the volume ratio of the conductive phase to the resistive phase in the resistor is less than about 70, less than about 60, less than about 50, less than about 30, less than about 25, less than about 15, less than about 10, or less than about 5.

In various embodiments, the resistivity of the reflective electronic layer of the present invention may be greater than about 1,000 μΩ-cm, e.g., greater than about 10,000 μΩ-cm, greater than about 100,000 μΩ-cm or greater than about 1,000,000 μΩ-cm. Of course, to constitute a “resistor,” the reflective electronic layer of the some aspects of the present invention must exhibit some degree of resistivity. As used herein, a “resistor” has a resistivity greater than about 100 μΩ-cm. In terms of ranges, the reflective electronic layers of these aspects of the present invention optionally have a resistivity ranging from about 100,000 to about 1,000,000, e.g., from about 1,000,000 to about 10,000,000, from about 100,000,000 to about 1,000,000,000, from about 10,000,000,000 to about 100,000,000,000 or from about 100,000,000,000 to about 1,000,000,000,000 μΩ-cm or greater.

Depending on their desired uses, the reflective electronic layers of the invention may have low-ohm, mid-ohm or high-ohm resistive properties. As used herein, a low-ohm resistor has a resistance of not greater than about 10 Ω/square, such as from about 0.2 to about 10 Ω/square. A mid-ohm resistor has a resistance of from about to about 10 Ω/square to about 10,000 Ω/square and a high-ohm resistor has a resistivity of at least about 10,000 Ω/square. The Table, below, illustrates the conversion of material resistivity to resistance for different exemplary feature thicknesses.

CONVERSION OF SHEET RESISTANCE

| | Resistivity (μΩ * cm) | | |
|---|---|---|---|
| Sheet Resistance | 2 μm thickness | 4 μm thickness | 6 μm thickness |
| 1 Ω/square | 200 | 400 | 600 |
| 100 Ω/square | 20,000 | 40,000 | 60,000 |
| 10,000 Ω/square | 2 × 10⁶ | 4 × 10⁶ | 6 × 10⁶ |
| 1,000,000 Ω/square | 2 × 10⁸ | 4 × 10⁸ | 6 × 10⁸ |

In various optional embodiments, the reflective electronic layer has a sheet resistance greater than 1 Ω/square, e.g., greater than 10 Ω/square, greater than 100 Ω/square, greater than 1,000 Ω/square, greater than 10,000 Ω/square, greater than 100,000 Ω/square, or greater than 1,000,000 Ω/square.

### Electroluminescent Lamps

In one embodiment, the invention is to novel electroluminescent (EL) lamps, and to processes for forming same, which include one or more reflective electronic layers. In a preferred aspect, the reflective electronic layer is conductive and functions as the back electrode of the EL lamp. In another aspect, the reflective electronic layer is a reflective dielectric layer, which is preferably disposed between the back electrode layer (which may or may not be reflective) and the phosphor layer. It is also contemplated that EL lamps may be formed having a reflective back electrode layer and a reflective dielectric layer.

In a first aspect, the invention is to an electroluminescent lamp, comprising: (a) a back electrode layer comprising metallic particles, the back electrode layer having a reflectivity greater than 20%, e.g., greater than 40%, greater than 60% or greater than 80%; (b) a dielectric layer disposed on the back electrode; (c) a phosphor layer disposed on the dielectric layer; and (d) a front electrode disposed on the phosphor layer.

In the first aspect, the increased reflectivity of the back electrode layer preferably results in a higher brightness EL lamp. A highly reflective back electrode increases the measured front light output relative to conventional EL lamps, which employ non-reflective back electrodes. The increase is due to the light that otherwise would be absorbed by the back electrode, but which according to this embodiment of the present invention is reflected off of the reflective back electrode and toward the front electrode.

Thus, the reflective electronic layer may be employed as a back electrode in an EL lamp. The lamp may further include a dielectric layer disposed on the back electrode; a phosphor layer comprising phosphor particles disposed on the dielectric layer; and a front electrode disposed on the phosphor layer. Alternatively, the lamp may include a composite layer disposed on the back electrode, the composite layer comprising phosphor particles and a dielectric; and a front electrode disposed on the composite layer. In this latter embodiment, the lamp optionally does not include a distinct, i.e., separate, dielectric layer.

In one aspect, which is particularly well suited for EL lamp applications, but which could be adopted for LED or other applications, the reflective electronic layer, e.g., reflective conductive layer, is formed in a pattern that displays variable information, e.g., information that may be easily changed such as serialized information (e.g., a serial number). As described in greater detail below, the ability to form reflective electronic layers through certain direct write printing processes such as ink jet printing processes, provides the ability to form reflective electronic layers that are capable of causing the EL lamp to display variable information.

In one embodiment, the back electrode, e.g., back electrode of an EL lamp, includes a first component comprising a reflective electronic layer and a second component comprising a non-reflective, optionally non-conductive, layer (i.e., having a reflectivity less than 12%). In this aspect, the second component preferably is disposed laterally, e.g., substantially in the same plane, with respect to the first component. The second component, e.g., non-reflective layer, may comprise a carbon back electrode or may comprise silver flakes, or may be non-conductive. By combining reflective and non-reflective electronic layers to form a single back electrode, EL lamps may be formed that exhibit regions having different brightnesses when in normal operation.

By incorporating reflective electronic layers in EL lamps, a EL lamps may be formed that exhibit a luminescence that is at least 15% greater than, e.g., at least 25% greater than, at least 40% greater than, or at least 60% greater than, a second lamp that comprises a non-reflective back electrode but is otherwise substantially identical to the first EL lamp.

In one embodiment, the EL lamp includes a protective layer disposed on the back electrode. In this aspect, the protective layer may comprise, for example, varnish (e.g., an acrylic varnish), a UV cured polymer, a plastic film, etc.

In another embodiment, the reflective electronic layer may include a plurality of regions that are independently addressable. This embodiment provides the ability to illuminate a plurality of various regions of an EL lamp independently of one another.

In another aspect, the invention provides a process for forming an electroluminescent lamp. The process includes the steps of: (a) depositing an ink comprising metallic particles and a vehicle onto a substrate; (b) removing the vehicle to form a conductive reflective back electrode layer; and (c) forming a dielectric layer disposed on the back electrode layer, a phosphor layer comprising phosphor particles disposed on the dielectric layer, and a front electrode disposed on the phosphor layer. The step of depositing may include printing with a printing process selected from the group consisting of gravure, offset, screen, flexography, direct write, syringe, and ink jet printing.

The composition of the ink may vary widely depending, for example, on the particles employed and on the printing process that is used to deposit the ink. The ink used to form the reflective electronic layer of certain embodiments of the present invention can either be a low viscosity ink or a paste, depending on the method used for depositing the compositions on a substrate. The ink preferably comprises the above-described metallic particles. Additionally, the ink preferably comprises a vehicle that is capable of stably dispersing the metallic particles. Optionally, the ink may also includes one or more additives such as one or more dispersants or dyes.

Depending on the formulation, the inks may be useful in a number of different printing methods, including, e.g., screen, lithographic, gavure, flexo, photopatterning, syringe, aerosol jetting, piezo-electric, thermal, drop-on-demand or continuous ink jet printing, preferably ink-jet printing or direct write printing. Although highly dependant on material and the specific printing process being implemented, in various embodiments, the particle loading in the inks is at least about 2% by weight, e.g., at least about 5% by weight, at least about 10% by weight, at least about 15% by weight, at least about 20% by weight, at least about 50% by weight, at least about 75% by weight, or at least about 85% by weight, based on the total weight of the total ink. Optionally, the total loading of the particles in the inks used to form the reflective electronic layers of the present invention is not higher than about 90% by weight, e.g., not higher than about 75% by weight, not higher than about 40% by weight, not higher than about 30%, not higher than about 20% by weight, not higher than about 10% by weight, or not higher than about 5% by weight, based on the total weight of the ink. In various embodiments, in terms of ranges, the ink optionally comprises from about 1 wt % to about 90 wt. %, e.g., from about 1 wt % to about 75 wt %, from about 1 wt % to about 60 wt. % metallic particles, from about 2 to about 40 wt. % metallic particles, from about 5 to about 25 wt. % metallic particles, or from about 10 to about 20 wt. % metallic particles, based on the total weight of the ink. In various other embodiments, the ink comprises from about 40 wt % to about 90 wt % metallic particles, e.g., from about 40 wt % to about 75 wt. % metallic particles, from about 40 to about 60 wt. % metallic particles, based on the total weight of the ink. Loadings in excess of these loadings can lead to undesirably high viscosities and/or undesirable flow characteristics. Of course, the maximum loading that still affords useful results also depends on the density of the metallic particles. In other words, for example, the higher the density of the metal of the metallic particles, the higher will be the acceptable and desirable loading in weight percent.

The inks preferably comprise a vehicle in addition to the metallic particles. In one embodiment, the inks further comprise an anti-agglomeration substance, for example, a polymer or surfactant. A preferred polymer coating for the metallic particles is polyvinyl pyrrolidone (PVP), which is well-suited for forming stable ink compositions, particularly low viscosity ink compositions suitable for direct write printing techniques such as ink jet printing. See U.S. patent application Ser. No. 11/755,720, filed May 30, 2007, the entirety of which is incorporated herein by reference, for processes for forming metallic particles having a PVP coating thereon. The vehicle for use in the inks is preferably a liquid that is capable of stably dispersing the metal-containing particles. For example, vehicles are preferred that are capable of affording an ink that can be kept at room temperature for several days or even one, two, three weeks or months or even longer without substantial agglomeration and/or settling of the metallic particles. To this end, it is also preferred for the vehicle to be compatible with the surface of the metallic particles. In one embodiment, the vehicle comprises (or predominantly consists of) one or more polar components (solvents) such as, e.g., a protic solvent, or one or more aprotic, non-polar components, or a mixture thereof. The vehicle, in an embodiment, is a solvent selected from the group consisting of alcohols, polyols, amines, amides, esters, acids, ketones, ethers, water, saturated hydrocarbons, unsaturated hydrocarbons, and mixtures thereof.

In some embodiments, the vehicle comprises a mixture of at least two solvents, optionally at least two organic solvents, e.g., a mixture of at least three organic solvents, or at least four organic solvents. The use of more than one solvent is preferred because it allows, inter alia, to adjust various properties of the ink simultaneously (e.g., viscosity, surface tension, contact angle with intended substrate etc.) and to bring all of these properties as close to the optimum values as possible. In one embodiment, the vehicle comprises a mixture of ethylene glycol, ethanol and glycerol. Non-limiting examples of vehicles are disclosed in, e.g., U.S. Pat. Nos. 4,877,451; 5,679,724; 5,725,647; 5,837,041; 5,837,045 and 5,853,470, the entire disclosures of which are incorporated by reference herein. In another embodiment, the vehicle comprises water, optionally primarily water.

In some embodiments according to the present invention, and in particular for screen printing applications, the ink has a viscosity of greater than about 5,000 cps, e.g., greater than 7,000 cps and greater than 10,000 cps. In other embodiments that are particularly suited for ink jet printing applications, the ink has a viscosity of less than about 100 cps, e.g., less than about 50 cps, less than about 10 cps, less than about 5 cps and less than about 1 cps. In still other embodiments, the ink has a viscosity of from about 50 cps to about 300 cps, e.g., from about 50 cps to about 200 cps and from about 50 to about 100 cps. Optionally, the ink has a surface tension of from about 20 dynes/cm to about 60 dynes/cm, e.g., from about 20 dynes/cm to about 40 dynes/cm.

The ink comprising the metallic particles optionally further comprises one or more additives, such as, but not limited to, resins (e.g., 20 wt % of an ethyl cellulose solution in terpineol), dispersants, thickeners, adhesion promoters, rheology modifiers, surfactants (e.g., sodium dilaureth phosphonate 10 (DLP-10)), wetting angle modifiers, humectants (e.g., glycerol, ethylene glycol, 2-pyrrolidone, and 1,5-pentanediol), crystallization inhibitors (e.g., 29,000 MW PVP), binders, dyes/pigments and the like. Non-limiting examples of adhesion promoters include shellac, latex, acrylates, other polymers, metal or a main group oxide (e.g., SiO₂, CuO, Bi₂O₃, PbO, or ZnO). Additional examples of adhesion promoters are described in U.S. Pat. No. 5,750,194, which is herein fully incorporated by reference. Non-limiting examples of rheology modifiers include JEFFAMINE (Huntsman) SOLTHIX 250 (Lubrizol), SOLSPERSE 21000 (Lubrizol), styrene allyl alcohol (SAA), ethyl cellulose, carboxy methylcellulose, nitrocellulose, polyalkylene carbonates, ethyl nitrocellulose, and the like. Non-limiting examples of binders include latex, shellac, acrylates, and the like. Cohesion promoters may also be included in the ink to improve reflective feature durability.

Optionally, the ink comprises one or more dyes or pigments, which alter the color or hue of the ultimately formed reflective electronic layer. For example, combining a red dye with silver metallic particles creates reflective electronic layers having a rose-colored silver reflectivity.

Additionally, the inks can optionally be formulated according to the methods described in U.S. Pat. Nos. 5,662,286; 5,624,485; 4,567,213; 4,390,369; 5,662,736; 5,596,027; 5,786,410; 5,643,356; 5,642,141, the entireties of which are incorporated herein by reference. Also, the inks can optionally be formulated according to the methods described in published PCT Application No. WO94/03546, the entirety of which is incorporated herein by reference. Finally, the inks can optionally be formulated according to the methods described in European Patent Application Nos. EP0745479; EP0805192; EP0745651; and EP0952195, the entireties of which are incorporated herein by reference. See also, U.S. patent application Ser. No. 11/755,720, filed May 30, 2007, the entirety of which is incorporated herein by reference.

As indicated above, the step of depositing may include a step of printing in a pattern to display variable information. Direct write printing processes, and in particular ink jet printing processes, are particularly well suited for forming reflective electronic layers in a pattern to display variable information.

The process may further include the step of: (d) forming a non-reflective back layer, e.g., disposed laterally in the same plane with respect to the reflective back electrode. This process may be used to form the above-described EL lamp having regions with different brightnesses when in normal operation. The non-reflective back layer may include a carbon back electrode or silver flakes, and may or may not be electrically conductive.

In another embodiment, the process may further include the step of forming a protective layer on the front electrode.

In yet another aspect, the invention provides a process for forming an electroluminescent lamp. The process comprises the steps of: (a) providing a multi-layered structure comprising: a dielectric layer; a phosphor layer disposed on a first surface of the dielectric layer; and a front electrode disposed on the phosphor layer; (b) depositing an ink comprising metallic particles and a vehicle onto a second surface of the dielectric layer; and (c) removing the vehicle to form a reflective back electrode layer, wherein the reflective back electrode layer has a reflectivity greater than 20%, e.g., greater than 40%, greater than 60% or greater than 80%.

After deposition of the ink onto a substrate, the ink comprising the metallic particles preferably is treated such that the ink forms at least a portion of the reflective feature. The treatment can include multiple steps, or can occur in a single step, such as when the ink is rapidly heated and held at the conversion temperature for a sufficient amount of time to form the reflective electronic layer. Heating can be accomplished using furnaces, light sources such as heat lamps and/or lasers. The reflective electronic layer can be post-treated after its formation. For example, the crystallinity of the phases present can be increased, such as by laser processing. The post-treatment can also include cleaning and/or encapsulation of the reflective electronic layer, or other modifications.

In some embodiments, the treatment that forms the reflective electronic layer involves heating the ink to a temperature from about 150° C. to about 1000° C., e.g., from about 150° C. to about 400° C., from about 200° C. to about 550° C., from about 300° C. to about 400° C., from about 400° C. to about 1000° C., from about 700° C. to about 1000° C., or from about 400° C. to about 700° C., to form the reflective electronic layer on the substrate. Heating of the ink at the aforementioned temperatures preferably causes the metallic particles to sinter, thus affording a percolation network of metallic particles. The resulting reflective electronic layer thus preferably comprises a percolation network of metallic particles.

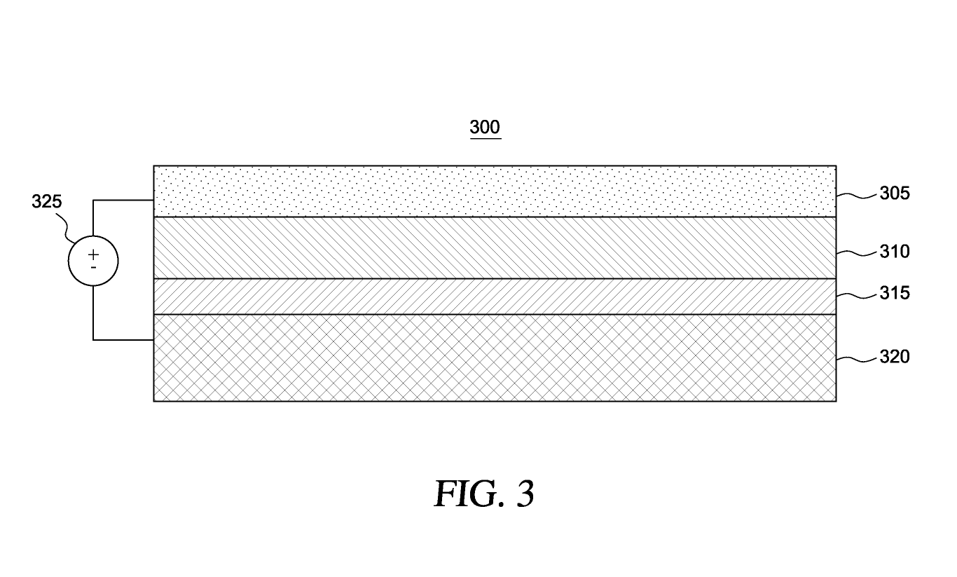

Referring to FIG. 3, an exemplary structure 300 for an EL lamp according to a preferred embodiment of the present invention includes a front electrode 305, a phosphor layer 310, a dielectric layer 315, and a reflective back electrode 320. The dielectric layer 315 is disposed on the back electrode 320; the phosphor layer 310 is disposed on the dielectric layer 315; and the front electrode 305 is disposed on the phosphor layer 310. The phosphor layer 310 includes phosphor particles. A source of electric power 325 is connected between the front electrode 305 and the back electrode 320. When the power source 325 is activated, the phosphor particles are excited, which causes the electroluminescent lamp to emit light. An additional protective layer (not shown), such as a polyester layer, may be disposed on the reflective back electrode 320.

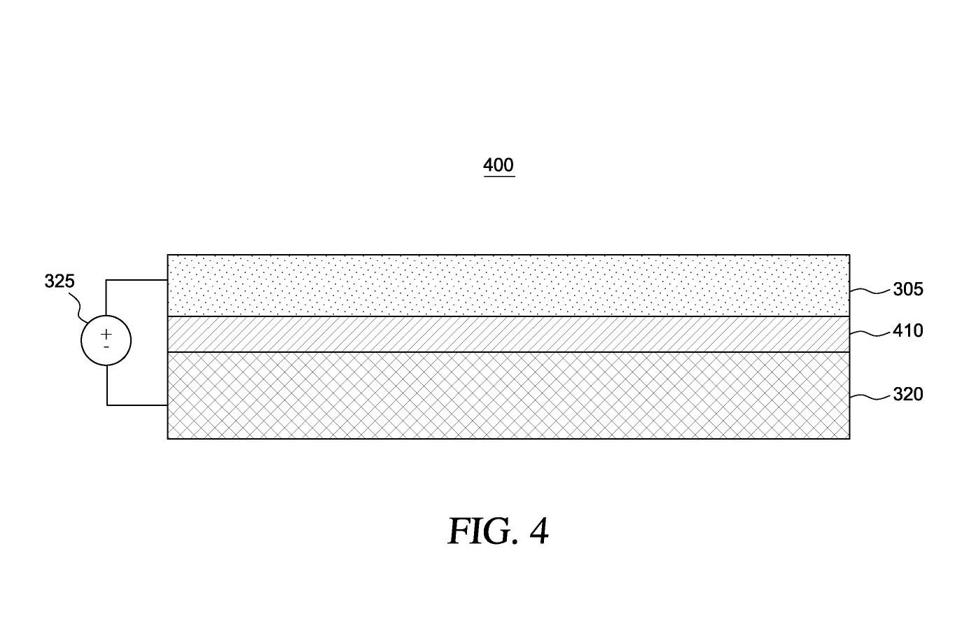

Referring to FIG. 4, a second exemplary structure 400 for an EL lamp according to a second preferred embodiment of the present invention includes a front electrode 305, a composite layer 410, and a reflective back electrode 320. The power source 325 is connected between the front and back electrodes 305, 320. The composite layer 410 includes a mixture of phosphor particles and dielectric particles, and is disposed on the back electrode 320. The front electrode 305 is disposed on the composite layer 410. An additional protective layer (not shown) may be disposed on the reflective back electrode 320.

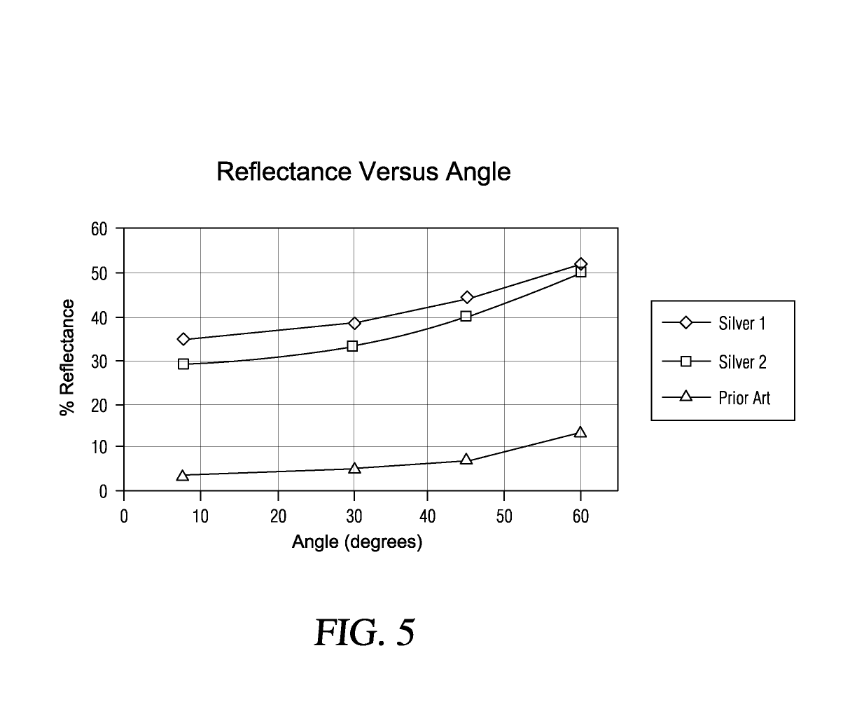

Referring to FIG. 5, a graphical illustration of reflectance versus angle of incidence is shown for empirical data obtained using several materials to form the back electrode. In one exemplary embodiment, when a first reflective silver paste (Silver 1) comprising PVP-coated silver nanoparticles is deposited onto the substrate to form the reflective back electrode, the reflectivity varies from about 35% to over 50% as the angle of incidence increases from less than 10 degrees to about 60 degrees. Similarly, when a second reflective silver paste (Silver 2) comprising silica-coated silver nanoparticles is deposited onto the substrate to form the reflective back electrode, the reflectivity varies from about 30% to about 50% as the angle of incidence increases from less than 10 degrees to about 60 degrees. By contrast, when a diffuse metal flake is used to form a non-reflective back electrode, the reflectivity varies between less than 5% and slightly above 10% as the angle of incidence increases from less than 10 degrees to about 60 degrees. Thus, the use of metallic particles, e.g., metallic nanoparticles, to form a reflective back electrode has a demonstrable effect of increasing the reflectivity of the electroluminescent lamp by at least 30% to 40% or more over a wide range of angles of incidence.

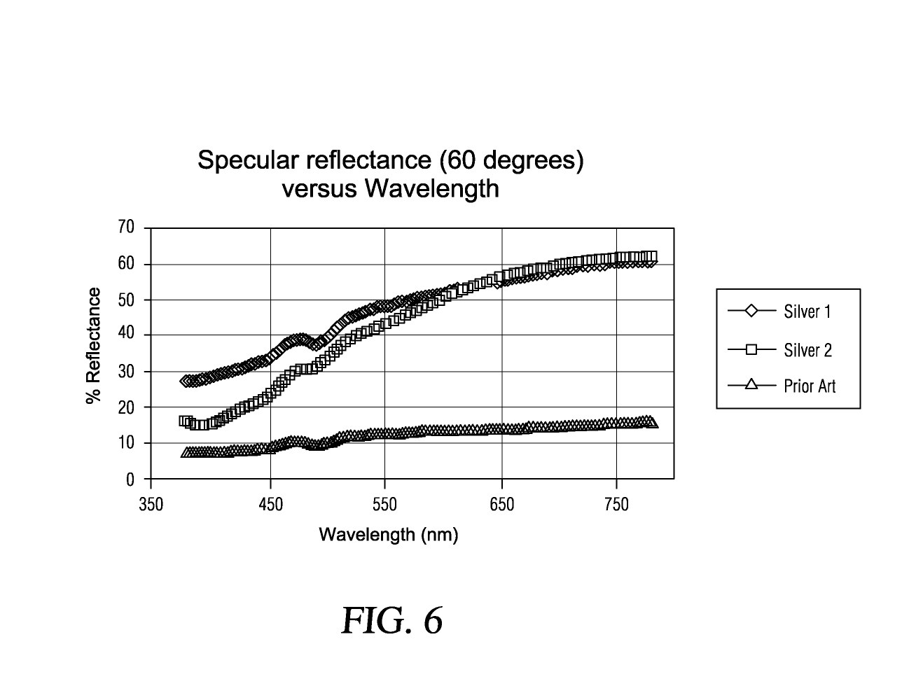

Referring to FIG. 6, a graphical illustration of reflectivity versus wavelength is shown for the visible light portion of the electromagnetic spectrum, i.e., approximately 370 nm to approximately 770 nm. In the illustration of FIG. 6, the angle of incidence is 60 degrees, and the same three types of metallic particles and flakes as in FIG. 5 are used to form the back electrode. In the exemplary embodiment in which Silver 1 paste (PVP-coated silver nanoparticles) is used to form a reflective back electrode, the reflectivity varies between about 27% and 61% over the visible light portion of the spectrum. Similarly, in the exemplary embodiment in which Silver 2 paste (Silica-coated silver nanoparticles) is used to form a reflective back electrode, the reflectivity varies between about 17% and 62% over the visible light portion of the spectrum. By contrast, when a diffuse metal flake is used to form a non-reflective back electrode, the reflectivity varies between about 8% and 15% over the same portion of the spectrum. Thus, the use of metallic particles, e.g., metallic nanoparticles to form a reflective back electrode has a demonstrable effect of increasing the reflectivity of the electroluminescent lamp by at least 10% to 45% or more over the full range of visible light wavelengths.

Therefore, as illustrated in FIGS. 5 and 6, the use of metallic particles to form a reflective back electrode according to a preferred embodiment of the present invention may have the effect of significantly increasing the reflectivity of the electroluminescent lamp. This increased reflectivity directly translates into an increased luminescence for EL lamp applications. Accordingly, in an exemplary embodiment of the invention, the luminescence of a first electroluminescent lamp that includes a reflective back electrode is at least 15% greater than, e.g., at least 25% greater than, the luminescence of a second electroluminescent lamp that has a non-reflective back electrode but is otherwise substantially identical to the first lamp.

The EL lamp having a reflective back electrode according to a preferred embodiment of the present invention has many possible applications. For example, the EL lamp may be used for a wide variety of displays, including displays that use back lighting, plasma televisions, and cathode ray tube (CRT) displays. The reflective electronic layer may be used to display variable information.

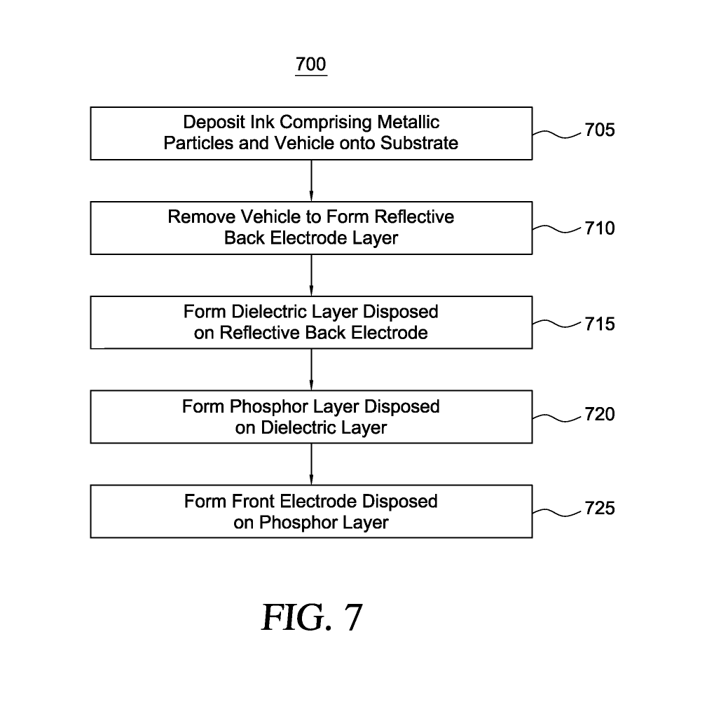

Referring to FIG. 7, a flowchart 700 illustrates a process for forming an EL lamp having a reflective back electrode according to a preferred embodiment of the present invention. In the first step 705, an ink that comprises metallic particles and a vehicle is deposited onto a substrate. The metallic particles may include metallic microparticles, e.g., particles having an average particle size of less than about 100 μm, or metallic nanoparticles, e.g., particles having an average particle size of less than about 500 nm, such as, for example, silver nanoparticles or gold nanoparticles. In the second step 710, the vehicle is removed, e.g., through heating, to form a reflective back electrode layer. Then, at step 715, a dielectric layer is formed on the reflective back electrode layer, and then a phosphor layer is formed on the dielectric layer at step 720. Finally, at step 725, a front electrode is formed on the phosphor layer. Optionally, a protective layer may be formed on the front electrode.

The depositing step 705 may include printing the ink onto the substrate using any of several known printing processes, such as, for example, gravure, offset printing, screen printing, flexography, direct write printing, syringe, or ink jet printing. The depositing step 705 may include printing the ink in a pattern for the purpose of using the EL lamp to display variable information.

The ability to vary the thickness of the reflective back electrode may be manifested in the back electrode layer having regions of relatively greater and lesser thicknesses. When an electroluminescent lamp having a reflective back electrode with regions of varying thickness is formed, the process 700 may further include the steps of aligning a portion of the lamp having a region of greater thickness with a corner of an object, and bending the lamp around the corner.

The process 700 may also include the step of forming an additional, non-reflective back electrode, for example a conventional carbon back electrode or a conventional silver flake back electrode, that is disposed laterally in the same plane as the reflective back electrode. By virtue of the inclusion of both a reflective back electrode and a non-reflective back electrode in the same electroluminescent lamp, the lamp may include regions having different brightnesses (i.e., different values of luminescence) when in normal operation.

In an alternative embodiment, steps 715 and 720 may be replaced by a step of forming a composite layer disposed on the reflective back electrode layer. The composite layer includes a mixture of a dielectric material and phosphor particles.

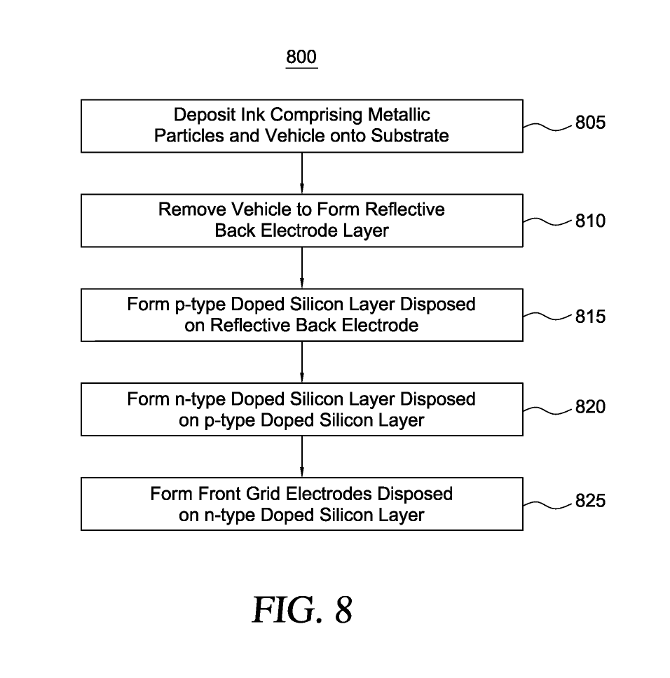

Referring to FIG. 8, a flowchart 800 illustrates a process for forming a photovoltaic feature having a reflective back electrode according to a preferred embodiment of the present invention. In the first step 805, an ink that comprises metallic particles and a vehicle is deposited onto a substrate. The metallic particles may include metallic microparticles, e.g., particles having an average particle size of less than about 100 μm, or metallic nanoparticles, e.g., particles having an average particle size of less than about 500 nm, such as, for example, silver nanoparticles or gold nanoparticles. In the second step 810, the vehicle is removed, e.g., through heating, to form a reflective back electrode layer. Then, at step 815, a p-type doped silicon layer is formed on the reflective back electrode layer, and then an n-type doped silicon layer is formed on the p-type doped silicon layer at step 820. As an alternative to the formation of the p-type and n-type doped silicon layers, a substrate having p-type doped silicon on one surface and n-type doped silicon on the opposite surface may be used. Finally, at step 825, a series of front grid electrodes are formed on the n-type doped silicon layer. Optionally, a protective layer may be formed on the grid of front electrodes.

Similarly as in the EL lamp forming process 700, the depositing step 805 may include printing the ink onto the substrate using any of several known printing processes, such as, for example, gravure, offset printing, screen printing, flexography, direct write printing, syringe, or ink jet printing. The reflective electronic layer may have a reflectivity that is greater than 20%, greater than 60% at a wavelength of 750 nm, greater than 60% at a wavelength of 400 nm, greater than 80%, or that is substantially specular. The reflective back electrode may have a thickness of less than about 250 nm.

### Photovoltaic Devices

In another embodiment, the reflective electronic layer, e.g., reflective conductive layer, is employed as a back electrode in a photovoltaic device or cell, e.g., a solar cell, and in particular a crystalline silicon photovoltaic cell. Conventional crystalline silicon photovoltaic cells include a series of front grid electrodes (referred to herein collectively as the front electrode) connected by bus bars, and a back electrode. Between the two electrodes are, from the back electrode to front electrode, a p-type silicon layer (e.g., doped with boron) and an n-type silicon (e.g., doped with phosphorous) layer. The back electrode is in electrical contact with the p-type silicon layer, and the front electrode is in electrical contact with the n-type silicon layer. Typically a passivation or antireflective layer, e.g., silicon nitride layer, is disposed on the n-type silicon layer in the regions that are not covered by the front electrode, e.g., between the gaps formed by the series of front grid electrodes.

In conventional crystalline silicon photovoltaic cells, the back electrode is formed of aluminum and is non-reflective. By incorporating a reflective electronic layer, e.g., reflective conductive layer, of the invention as the back electrode of a photovoltaic cell according to this aspect of the invention, some amount of incident light is reflected off of the back electrode and increases the total quantity of photons that may excite the emitter layer, thereby increasing photovoltaic cell electrical output and efficiency.

Thus, in one embodiment, the invention is to a photovoltaic device comprising: (a) a semiconductor substrate; (b) a front grid electrode disposed on a first side of the semiconductor substrate; and (c) a back electrode disposed on a second side of the semiconductor substrate, the back electrode comprising a printed reflective electronic layer comprising metallic particles, wherein the printed reflective electronic layer has a reflectivity greater than 20%, e.g., greater than 40%, greater than 60%, or greater than 80%. As discussed above, the metallic particles preferably have an average particle size of less than 300 nm, less than 200 nm or less than 100 nm. The semiconductor substrate preferably comprises an n-type silicon layer and a p-type silicon layer.

In another embodiment, the invention is to a process for forming a photovoltaic device, comprising: (a) forming a front grid electrode on a first side of a semiconductor substrate; (b) depositing an ink comprising metallic particles, e.g., metallic particles having an average particle size less than 300 nm, less than 200 nm or less than 100 nm, and a vehicle onto a second side of the semiconductor substrate; and (c) removing the vehicle to form a printed reflective electronic layer, wherein the printed reflective electronic layer is a back electrode of the photovoltaic device. The ink employed in this embodiment may be substantially similar to the inks described above with reference to the processes for forming EL lamps, and may vary depending on the printing process employed. The step of depositing optionally comprises printing with a printing process selected from the group consisting of gravure, offset, screen, flexography, direct write, syringe, and ink jet printing. In this embodiment, the printed reflective electronic layer preferably has a reflectivity greater than 20%, greater than 40%, greater than 60% or greater than 80%.

Although the above embodiments contemplate use of reflective back electrode layer in photovoltaic devices, it is also contemplated that in various other embodiments, the reflective layer may be printed on the front and/or intermediate layers and optionally any connecting vias therebetween.

### Light Emitting Diodes

LEDs are diodes that emit light when connected in a circuit. They typically comprise two leads or electrodes, the terminal ends of which are disposed within an insulating enclosure, e.g., epoxy enclosure. The cathode lead typically ends in a flat surface, on which a reflector element is disposed. On the surface of the reflector element is a LED semiconductor chip. The semiconductor chip comprises two regions, a p region and an n region, which are separated by a junction. When sufficient voltage is applied to the semiconductor chip, current flows and electrons cross the junction from the n region to the p region. The electrons are then attracted to the positive charge of the anode, resulting in recombining of the charges. As the electrons recombine with the positive charge of the anode, electric potential energy is converted to electromagnetic energy, thereby emitting photons of light with a frequency that is dependant on the semiconductor material that is employed (e.g., a combination of chemical elements gallium, arsenic and phosphorous). In a preferred embodiment, wide band gap semiconductors such as gallium nitride and/or indium gallium nitride are employed.

In one embodiment, the invention is to an LED comprising a reflective electronic layer in the form of a reflective electrode or lead (e.g., anode, cathode or both). The reflective electrode preferably comprises metallic particles, e.g., having an average particle size of less than 300 nm, e.g., less than 200 nm or less than 100 nm. The reflective electrode or lead optionally has an average reflectivity greater than 20%, e.g., greater than 40%, greater than 60% or greater than 80%, over a wavelength from 300 to 750 nm (optionally over a wavelength from 250 to 25,000 nm). In this aspect, the reflective electrode reflects light from the LED chip and no separate reflector element is required (although one may optionally be included). Thus, the LED chip itself may be secured directly to the reflective electrode, e.g., cathode, without an intervening reflector element. Optionally, the terminal end of the reflective electrode, e.g., cathode, is shaped in a manner that maximizes the effective reflectivity of the light emitted from the LED chip, for example, the electrode may include a parabolic reflective region, which houses the LED chip.

The extreme reflectivity obtainable by employing metallic nanoparticles may result in increased reflectivity, and hence, reduced loads and potentially longer product lifetime, e.g., estimated average time to failure on the order of more than 500,000 hours, more than 1,000,000 hours, more than 1,200,000 hours or more than 1,500,000 hours.

The above-described reflective electrodes (leads) and reflectors may be formed, for example, by depositing an ink comprising the metallic particles and a vehicle onto a surface of the anode lead, and removing the vehicle to form the reflector. After the reflector is formed, the LED chip is secured thereto and the leads are secured within the insulating enclosure.

While the present invention has been described with respect to what is presently considered to be the preferred embodiment, it is to be understood that the invention is not limited to the disclosed embodiments. To the contrary, the invention is intended to cover various modifications and equivalent arrangements included within the spirit and scope of the appended claims. The scope of the following claims is to be accorded the broadest interpretation so as to encompass all such modifications and equivalent structures and functions.

What is claimed is:

1. An electronic device comprising a printed reflective electronic layer comprising metallic particles having an average particle size less than 300 nm, wherein the printed reflective electronic layer has an average reflectivity greater than 20% over a wavelength from 300 to 750 nm, and the printed reflective electronic layer has a resistivity greater than 1 Ω/square.

2. The electronic device of claim 1, wherein the reflective electronic layer has an average reflectivity greater than 80% over a wavelength of 300 to 750 nm.

3. The electronic device of claim 1, wherein the reflective electronic layer has an average reflectivity greater than 20% over a wavelength from 250 to 25,000 nm.

4. The electronic device of claim 1, wherein the resistivity is greater than 100 Ω/square.

5. The electronic device of claim 1, wherein the reflective electronic layer has resistivity greater than 1,000 Ω/square.

6. The electronic device of claim 1, wherein the reflective electronic layer has resistivity greater than 1,000,000 Ω/square.

7. The electronic device of claim 1, wherein the metallic particles comprise a coating comprising glass, a metal oxide or a polymer.

8. The electronic device of claim 1, wherein the metallic particles have an average particle size of less than 100 nm.

9. The electronic device of claim 1, wherein the device is an electroluminescent lamp and the reflective electronic layer is a reflective dielectric layer in the electroluminescent lamp, and wherein the reflective dielectric layer further comprises a dielectric material.

10. The electronic device of claim 1, wherein the device is a light emitting diode, and the reflective electronic layer acts as a reflective electrode.

11. An electroluminescent lamp, comprising a first electrode layer comprising metallic particles, the first electrode layer having an average reflectivity greater than 20% over a wavelength from 300 to 750 nm.

12. The electroluminescent lamp of claim 11, further comprising:
either (i) a dielectric layer and a phosphor layer, or (ii) a composite layer comprising a dielectric material and a phosphor material; and
a second electrode.

13. The electroluminescent lamp of claim 11, wherein the metallic particles have an average particle size of less than 300 nm.

14. A process for forming an electrode for an electroluminescent lamp, comprising depositing an ink comprising metallic particles and a vehicle onto a substrate and removing the vehicle to form a first electrode layer, wherein the first electrode layer has an average reflectivity greater than 20% over a wavelength from 300 to 750 nm.

15. The process of claim 14, wherein the substrate comprises:
either (i) a dielectric layer and a phosphor layer, or (ii) a composite layer comprising a dielectric material and a phosphor material; and
optionally a second electrode layer.

16. The process of claim 14, wherein the first electrode layer has an average reflectivity greater than 80% over a wavelength from 300 to 750 nm.

17. The process of claim 14, wherein the metallic particles have an average particle size of less than 300 nm.

18. A photovoltaic device comprising:
(a) a semiconductor substrate;
(b) a front grid electrode disposed on a first side of the semiconductor substrate; and
(c) a back electrode disposed on a second side of the semiconductor substrate, the back electrode comprising a printed reflective electronic layer comprising metallic particles, wherein the printed reflective electronic layer has an average reflectivity greater than 20% over a wavelength from 300 to 750 nm.

19. The photovoltaic device of claim 18, wherein the metallic particles have an average particle size of less than 300 nm.

20. The photovoltaic device of claim 18, wherein the semiconductor substrate comprises an n-type silicon layer and a p-type silicon layer.

21. The photovoltaic device of claim 18, wherein the first electrode layer has an average reflectivity greater than 80% over a wavelength of 300 to 750 nm.

22. A process for forming a photovoltaic device, comprising:
(a) forming a front grid electrode on a first side of a semiconductor substrate;
(b) depositing an ink comprising metallic particles and a vehicle onto a second side of the semiconductor substrate; and
(c) removing the vehicle to form a reflective electronic layer, wherein the reflective electronic layer is a back electrode of the photovoltaic device, and wherein the reflective electronic layer has an average reflectivity greater of than 20% over a wavelength from 300 to 750 nm.

23. The process of claim 22, wherein the step of depositing comprises printing with a printing process selected from the group consisting of gravure, offset, screen, flexography, direct write, syringe, and ink jet printing.

24. The process of claim 22, wherein the metallic particles have an average particle size of less than 300 nm.

25. The process of claim 22, wherein the printed reflective electronic layer has an average reflectivity greater than 80% over a wavelength from 300 to 750 nm.
